(19) United States
(12) Patent Application Publication
(10) Pub. No.: US 2026/0206629 A1
(43) Pub. Date: Jul. 16, 2026

(54) SEMICONDUCTOR CHIP BONDING APPARATUS AND FUME COLLECTION METHOD THEREOF

(71) Applicant: HANMI SEMICONDUCTOR CO., LTD., Incheon (KR)

(72) Inventor: Jun Su Byun, Incheon (KR)

(21) Appl. No.: 19/419,148

(22) Filed: Dec. 15, 2025

(30) Foreign Application Priority Data
Jan. 15, 2025 (KR) 10-2025-0006342

(51) Int. Cl. H10W 72/00

(52) U.S. Cl. CPC H10W 72/07118; H10W 72/07125; H10W 72/07141; H10W 72/07173; H10W 72/07211; H10W 72/07232

(57) ABSTRACT

The present invention relates to a semiconductor chip bonding apparatus for applying flux to a lower surface of a semiconductor chip on which bumps are formed and bonding the semiconductor chip to a substrate by heating and pressing the flux-applied chip, and to a fume collection method thereof. The invention quickly collects and removes vaporized fume of flux generated during thermocompression bonding, preventing contamination of the semiconductor chip and the bonding tool and preventing fume from entering fine gaps that may cause malfunction of vacuum suction. Even if fume enters the tool passage and chip passage of the heating block and solidifies, it can be liquefied and vaporized, with liquefied fume dropping to the bottom surface in the fume collection unit while vaporized fume is suctioned and removed, enabling quick removal and maintaining the passages in good condition.

### CROSS REFERENCE TO RELATED APPLICATION

The present application claims priority to Korean Patent Application No. 10-2025-0006342, filed January 15, 2025, the entire contents of which are incorporated herein for all purposes by this reference.

### BACKGROUND OF THE INVENTION

### Field of the Invention

The present invention relates to a semiconductor chip bonding apparatus for applying flux to a lower surface of a semiconductor chip on which bumps are formed and bonding the flux-coated semiconductor chip to a substrate by thermocompression, and a fume collection method thereof.

### Description of the Related Art

A semiconductor chip bonding apparatus is a device for attaching a semiconductor chip to a substrate by applying flux to the bumps of the semiconductor chip, contacting the bumps with the connection terminals of the substrate, and thermocompression bonding the semiconductor chip to the substrate using heat and pressure through a bonding head.

The bonding head, while suctioning the semiconductor chip with flux or film (hereinafter referred to as " flux ") made of a thermosetting material applied to the bump-formed surface, moves the semiconductor chip to the upper portion of the substrate on the bonding table and then performs the operation of thermocompression bonding the semiconductor chip to the substrate.

Specifically, the bonding head is equipped with a heater to heat the semiconductor chip to a predetermined temperature. Through this, the bonding head can thermocompression bond the semiconductor chip to the substrate by heating the bumps and flux while suctioning the semiconductor chip.

During thermocompression bonding, the bonding head heats the bumps and flux of the semiconductor chip to a high temperature to melt them, and then cools the melted bumps and flux to approximately 100°C to fix the semiconductor chip to the substrate.

However, during the process of thermocompression bonding the semiconductor chip to the substrate by the bonding head, the bonding head is heated to a high temperature of approximately 200~400°C by the heater, causing the flux applied to the semiconductor chip to generate fume. Fume is gas or soot caused by the vaporized flux. Since flux is a thermosetting resin with properties that change state depending on temperature, it remains in a liquid state at room temperature and becomes gaseous due to volatile components when heated. The vaporized volatile components condense into a solid state when cooled.

The volatile components of the flux, which are vaporized by the heater of the bonding head during thermocompression bonding, can be suctioned into the vacuum flow path through fine gaps between the structures of the thermocompression bonding head or between the bonding tool and the semiconductor chip. The suctioned volatile components solidify while adhering inside the vacuum flow path, causing issues such as malfunction of the vacuum suction operation, reduction in suction force, and interference with the temperature increase of the heater.

Accordingly, a cleaning process is performed to remove the fume, which is the volatile component suctioned into the vacuum flow path.

However, in the conventional cleaning process, the operator must manually separate the bonding tool and the heating block from the bonding head and directly clean the inside of the vacuum flow path formed in the heating block, making the cleaning operation cumbersome and reducing the efficiency of the cleaning process. Additionally, the operator must wait until the heating block, which is heated to a high temperature during bonding, sufficiently cools down for manual cleaning, resulting in significant time consumption.

Therefore, there is a need for technology that allows for quick and simple cleaning of the inside of the flow path in the heating block and improves the efficiency of the cleaning process.

Furthermore, fume floating around the bonding tool may condense in the air and fall onto the substrate or the upper surface of the bonded semiconductor chip. This can contaminate the substrate to be bonded or the bonded semiconductor chip, causing bonding defects. Thus, it is necessary to quickly remove the generated fume to prevent it from spreading to the surroundings during bonding.

### Prior Art Documents

### Patent Documents

### Patent Document 1 Korean Registered Patent No. 10-2323539

### SUMMARY OF THE INVENTION

The present invention aims to provide a semiconductor chip bonding apparatus and a fume collection method thereof, which can remove fume by automatically cleaning the flow path inside the heating block of the bonding head without manually separating the heating block.

In addition, the present invention aims to provide a semiconductor chip bonding apparatus and a fume collection method thereof, which not only prevent contamination of the semiconductor chip and the bonding tool by collecting and removing vaporized fume of flux generated during thermocompression bonding, but also allow easy cleaning of the tool passage and the chip passage of the bonding head even if fume enters through fine gaps between the mechanical components of the bonding head or between the bonding tool and the semiconductor chip.

Furthermore, the present invention aims to provide a semiconductor chip bonding apparatus and a fume collection method thereof, which can perform cleaning with strong air pressure by using a separate flow path when cleaning the tool passage and the chip passage of the bonding head.

A semiconductor chip bonding apparatus according to one aspect of the present invention, for applying flux to a lower surface of a semiconductor chip on which bumps are formed, and bonding the semiconductor chip to a substrate by heating and pressing the semiconductor chip to which the flux is applied, the apparatus comprising: a bonding head, wherein the bonding head comprises: a bonding tool having a suction hole formed therein for suctioning a semiconductor chip; a heating block provided on an upper portion of the bonding tool, having a tool passage formed therein for attaching and detaching the bonding tool and a chip passage communicating with the suction hole, and including a heating member; a tool flow path communicating with the tool passage; a tool ejector for supplying negative pressure or positive pressure to suction or detach the bonding tool through the tool flow path; a chip flow path communicating with the chip passage; and a chip ejector for supplying negative pressure or positive pressure to suction or detach the semiconductor chip through the chip flow path; wherein the bonding head further comprises: a cleaning flow path communicating with the tool flow path and the chip flow path; and a cleaning air supply unit for supplying air to remove solidified fume inside the tool passage and the chip passage through the cleaning flow path.

In addition, the semiconductor chip bonding apparatus further comprises a fume collection unit for collecting fume discharged from the bonding head below a movement path of the bonding head, wherein the heating member heats the heating block in a state where the bonding tool is detached to liquefy and vaporize the solidified fume inside the tool passage and the chip passage, and the cleaning air supply unit supplies air to the tool passage and the chip passage to drop the liquefied and vaporized fume to the fume collection unit.

In addition, the heating member heats the heating block before cleaning the tool flow path and the chip flow path with the air supplied from the cleaning air supply unit or simultaneously with the air supply from the cleaning air supply unit.

In addition, the semiconductor chip bonding apparatus further comprises: a fume collection unit flow path communicating with the fume collection unit; and a dust collection pump for guiding the liquefied and vaporized fume dropping to the fume collection unit to the fume collection unit, and suctioning the vaporized fume through the fume collection unit flow path when dropping to the fume collection unit.

In addition, the bonding head further comprises a fume collection member disposed on an outer circumference of the heating block and collecting vaporized fume generated when thermocompression bonding the semiconductor chip, wherein the semiconductor chip bonding apparatus further comprises: a dust collection flow path having one end communicating with the fume collection member and the other end communicating with the fume collection unit flow path; and a recovery switching valve provided at a position where the fume collection unit flow path and the dust collection flow path communicate, and switching a suction direction of fume toward the fume collection unit flow path or the dust collection flow path, wherein the recovery switching valve is switched to suction the vaporized fume through the dust collection flow path when the bonding head thermocompression bonds the semiconductor chip, and suction the vaporized fume through the fume collection unit flow path when the fume collection unit collects the liquefied and vaporized fume from the bonding head.

In addition, the semiconductor chip bonding apparatus further comprises dust collection filters for filtering the suctioned fume, which are respectively provided on the fume collection unit flow path and the dust collection flow path.

In addition, the fume collection unit comprises a scattering prevention plate protruding in a downwardly inclined form toward a bottom surface of the fume collection unit on an upper portion of an inner wall of the fume collection unit so that when the liquefied and vaporized fume drops to the fume collection unit, the liquefied fume is guided to the bottom surface of the fume collection unit and does not adhere to the inner wall where the fume collection unit flow path communicates.

In addition, the bonding head further comprises: a tool valve provided between the tool ejector and the tool flow path to switch the cleaning flow path to communicate with the tool flow path or to switch the tool ejector to communicate with the tool flow path; a chip valve provided between the chip ejector and the chip flow path to switch the cleaning flow path to communicate with the chip flow path or to switch the chip ejector to communicate with the chip flow path; and a cleaning valve provided on one side of the cleaning air supply unit to selectively supply air.

In addition, the pressure of the air supplied from the cleaning air supply unit is greater than a positive pressure of the chip ejector.

A fume collection method of a semiconductor chip bonding apparatus according to another aspect of the present invention, for applying flux to a lower surface of a semiconductor chip on which bumps are formed, and bonding the semiconductor chip to a substrate by heating and pressing the semiconductor chip to which the flux is applied, comprises: separating a bonding tool from a heating block by supplying positive pressure to a tool passage in a bonding head including the heating block having the tool passage and a chip passage formed therein and including a heating member; liquefying and vaporizing solidified fume inside the tool passage and the chip passage by heating the heating member in a state where the bonding tool is separated; and a fume recovery step of, in a state where a tool valve and a chip valve are switched so that a cleaning flow path is connected to the tool passage and the chip passage, opening a cleaning valve to supply air through the tool passage and the chip passage to drop the liquefied and vaporized fume, and recovering the dropped fume to a fume collection unit.

In addition, the fume recovery step suctions the vaporized fume through a fume collection unit flow path when the liquefied and vaporized fume drops to the fume collection unit by opening a recovery switching valve.

The semiconductor chip bonding apparatus and the fume collection method thereof according to the present invention comprise a cleaning flow path and a cleaning valve, thereby having a structure capable of automatically performing a cleaning process for the tool passage and the chip passage by communicating the cleaning flow path with each of the tool flow path and the chip flow path after performing the thermocompression bonding process. As a result, when a cleaning process to remove fume suctioned into the tool passage and the chip passage of the bonding head is required after performing the thermocompression bonding process, the cleaning process can be automatically performed without requiring an operator to manually perform the cleaning process by separately detaching the heating block and the bonding tool of the bonding head, thereby improving the efficiency of the cleaning process.

In addition, the semiconductor chip bonding apparatus and the fume collection method thereof according to the present invention can perform an automatic cleaning process by comprising a cleaning flow path and a cleaning valve, allowing the use of high-pressure air during the cleaning process and low-pressure air using an ejector during the thermocompression bonding process. As a result, the apparatus is provided with a structure capable of using both high-pressure vacuum and low-pressure vacuum, thereby enhancing the efficiency of the processes of the semiconductor chip bonding apparatus itself.

Furthermore, the semiconductor chip bonding apparatus and the fume collection method thereof according to the present invention have the effect of being able to use air suitable for each purpose by not using the air for suctioning and separating the tool and the semiconductor chip, but instead using separate strong air pressure for cleaning the tool passage and the chip passage. This effect includes the ability to remove fume inside the passages during the cleaning of the passages without causing impact to the semiconductor chip or displacing its position due to excessive air when the bonding head handles the semiconductor chip.

Moreover, the semiconductor chip bonding apparatus and the fume collection method thereof according to the present invention can quickly collect and remove vaporized fume of flux generated during thermocompression bonding, thereby preventing contamination of the semiconductor chip and the bonding tool, and not only that, but also limits the inflow of fume into fine gaps of the bonding tool or between the bonding tool and the semiconductor chip, minimizing defects in the vacuum suction operation.

Additionally, the semiconductor chip bonding apparatus and the fume collection method thereof according to the present invention have the effect of enabling the cleaning of the tool passage and the chip passage without requiring separate heating means by liquefying and vaporizing the solidified fume in the tool passage and the chip passage of the heating block using the heating member of the bonding head and subsequently removing it.

Furthermore, the semiconductor chip bonding apparatus and the fume collection method thereof according to the present invention can quickly and easily remove fume by dropping the solidified fume in the tool passage and the chip passage of the heating block to the fume collection unit and suctioning the vaporized fume, thereby maintaining the tool passage and the chip passage in good condition.

### BRIEF DESCRIPTION OF THE DRAWINGS

The above and other features of embodiments of the disclosure will become apparent by describing in detail embodiments thereof with reference to the accompanying drawings.

FIG. 1 is a plan view of a semiconductor chip bonding apparatus according to a preferred embodiment of the present invention.

FIG. 2 is a diagram illustrating the flow of a cleaning process for removing solidified fume inside a tool passage and a chip passage.

FIG. 3 is a diagram illustrating the flow of a bonding process for thermocompression bonding a semiconductor chip.

FIG. 4 is a diagram schematically illustrating a fume collection method of a semiconductor chip bonding apparatus according to a preferred embodiment of the present invention.

### DETAILED DESCRIPTION OF THE INVENTION

The following content merely illustrates the principles of the invention. Therefore, those skilled in the art can implement the principles of the invention and invent various devices included in the concept and scope of the invention, even if they are not explicitly described or shown in this specification. Furthermore, all conditional terms and embodiments listed in this specification are, in principle, explicitly intended only for the purpose of understanding the concept of the invention and should not be understood as being limited to the specifically listed embodiments and conditions.

The aforementioned objectives, features, and advantages will become more apparent through the following detailed description in connection with the accompanying drawings, thereby enabling those skilled in the art to easily implement the technical idea of the invention.

The embodiments described in this specification will be explained with reference to the ideal illustrative sectional views and/or perspective views of the invention. The thicknesses of films and regions and the diameters of holes shown in these drawings are exaggerated for effective explanation of the technical content. The shapes in the illustrative drawings may be modified due to manufacturing techniques and/or tolerances.

Hereinafter, the preferred embodiments of the present invention will be described in detail with reference to the accompanying drawings as follows.

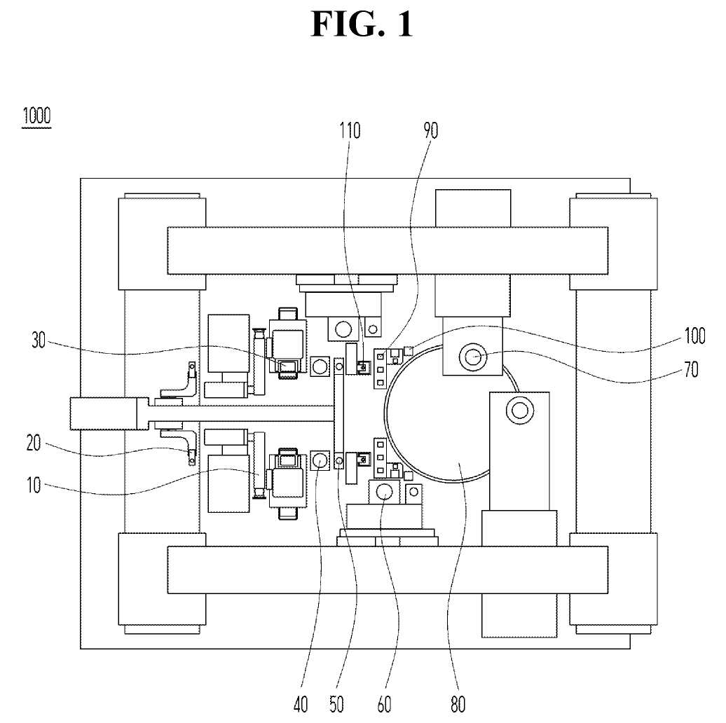

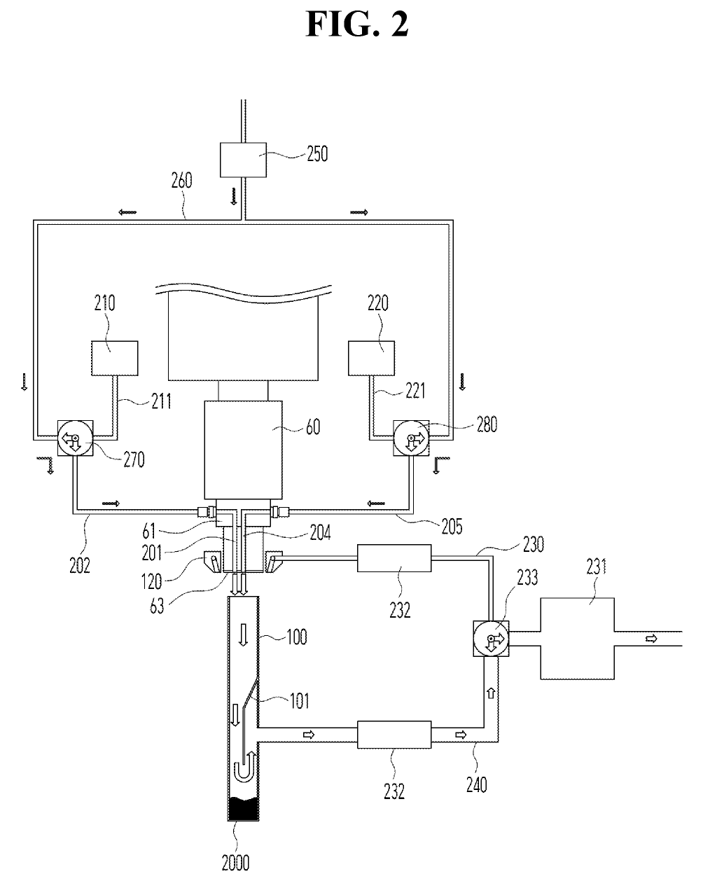

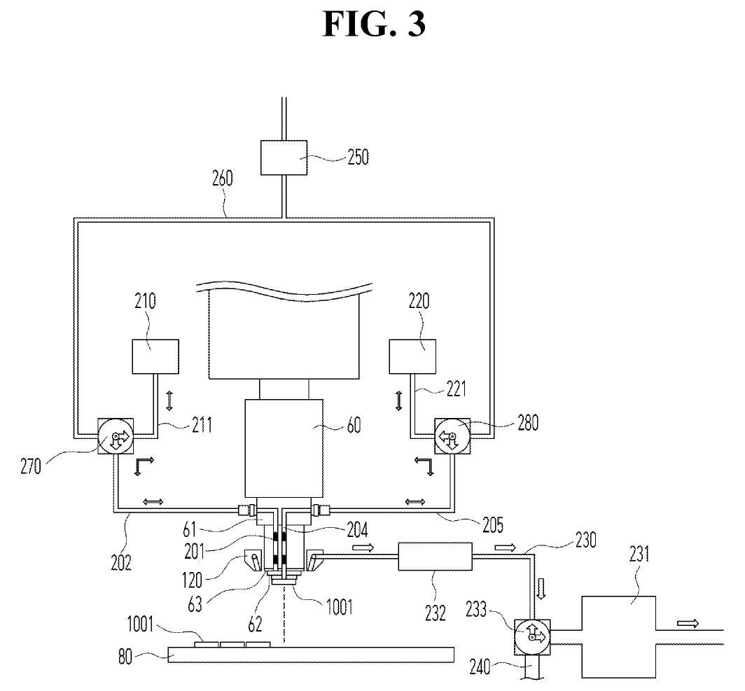

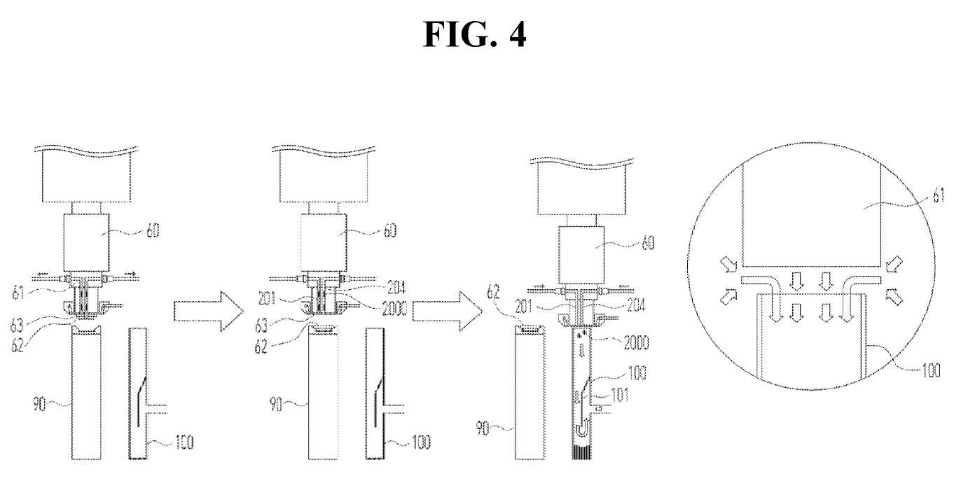

FIG. 1 is a plan view of a semiconductor chip bonding apparatus 1000 according to a preferred embodiment of the present invention, FIG. 2 is a diagram showing the flow of a cleaning process for removing solidified fume 2000 inside a tool passage and a chip passage, FIG. 3 is a diagram showing the flow of a bonding process for thermocompression bonding a semiconductor chip 1001, and FIG. 4 is a schematic diagram showing a fume collection method of the semiconductor chip bonding apparatus 1000 according to a preferred embodiment of the present invention.

Referring to FIG. 1, the semiconductor chip bonding apparatus 1000 of the present invention will be described.

The semiconductor chip bonding apparatus 1000 of the present invention comprises a flip-over picker 10 for suctioning a semiconductor chip 1001 on an adhesive film and flipping it upside down, a die picker 20 for receiving the semiconductor chip 1001 from the flip-over picker 10, suctioning it, and dipping one surface of the semiconductor chip 1001 into flux, a flux unit 30 for accommodating flux to dip the lower surface of the semiconductor chip 1001 picked up by the die picker 20 into the flux, an up-looking vision 40 for inspecting the lower surface of the semiconductor chip 1001 suctioned by the die picker 20, a die block 50 for temporarily placing the inspected semiconductor chip 1001, a bonding head 60 for suctioning the semiconductor chip 1001 dipped in flux on the die block 50 and thermocompression bonding it to a substrate, a slit vision 70 for capturing the alignment state between the upper surface of the substrate to be bonded and the semiconductor chip 1001 suctioned by the bonding head 60, a bonding table 80 where the thermocompression bonding process of the semiconductor chip 1001 is performed, a tool changer 90 where the bonding tool 62 detached from the bonding head 60 and the same or different types of bonding tools are mounted, a fume collection unit 100 for collecting fume 2000 discharged from the bonding head 60 through the cleaning process, and a reject picker 110 for dropping defective semiconductor chip 1001, determined by the inspection result of the up-looking vision 40, into a defect collection unit.

The flip-over picker 10 can suction the semiconductor chip 1001 from an adhesive film with individualized semiconductor chips 1001 attached and flip it upside down. The flip-over picker 10 is configured to be capable of ascending and descending and rotating 180 °. The flip-over picker 10 is positioned above the adhesive film to suction the bump-formed surface of the semiconductor chip 1001 on the adhesive film. At this time, the molding surface of the semiconductor chip 1001 faces downward based on the ascending and descending direction of the flip-over picker 10. The flip-over picker rotates 180 ° while suctioning the semiconductor chip. As a result, the semiconductor chip 1001 is flipped upside down, and its molding surface faces upward.

The die picker 20 picks up the semiconductor chip 1001 flipped upside down by the flip-over picker 10. The die picker 20 moves above the flip-over picker 10 and descends toward the semiconductor chip 1001 suctioned by the flip-over picker 10. The die picker 20 suctions the upper surface, which is the molding surface, of the semiconductor chip 1001. At this time, the semiconductor chip is suctioned to the die picker 20 through its upper surface, with the bump-formed surface facing downward. The die picker 20 moves above the flux unit 30 while holding the semiconductor chip 1001.

The flux unit 30 comprises a dipping plate for accommodating flux and a flux tank for supplying flux to the dipping plate. The flux tank is installed to be movable on the dipping plate and supplies flux to the dipping plate while leveling the flux on the dipping plate. The flux tank for accommodating flux is formed to be open at the lower side so that flux is supplied to the dipping plate through the lower side of the open flux tank.

The die picker 20 dips the bump-formed surface, which is the lower surface of the semiconductor chip 1001, into the flux in the flux unit 30 and then moves above the up-looking vision 40.

The up-looking vision 40 inspects the bump-formed surface of the semiconductor chip 1001 suctioned by the die picker 20 from below. Specifically, the up-looking vision 40 inspects the state of the lower surface of the semiconductor chip 1001 dipped in flux. The up-looking vision 40 inspects the flux application state on the lower surface of the semiconductor chip 1001 and can inspect conditions such as contamination, foreign substances, cracks, and bump defects.

The crack inspection of the semiconductor chip 1001 using the up-looking vision 40 is preferably performed before dipping the semiconductor chip 1001, which is suctioned by the die picker 20, into the flux. The crack inspection can be performed selectively. The semiconductor chip bonding apparatus 1000 can check for cracks on the lower surface (bump formation surface) of the semiconductor chip 1001, which is suctioned by the die picker 20, through the up-looking vision 40 before dipping the lower surface of the semiconductor chip 1001 into the flux. Then, if no cracks are present on the lower surface (bump formation surface) of the semiconductor chip 1001, the die picker 20 can immerse the lower surface of the semiconductor chip 1001 into the flux. Afterward, the state of the lower surface (bump formation surface) of the semiconductor chip 1001 with flux applied can be inspected again through the up-looking vision 40.

The die picker 20, after completing the inspection of the lower surface of the semiconductor chip 1001 through the up-looking vision 40, moves above the die block 50. The die block 50 is positioned between the die picker 20 and the bonding head 60 and is fixedly arranged on the movement path of the die picker 20 moving toward the bonding head 60. The die picker 20 transfers the semiconductor chip 1001 with flux applied to the die block 50. The die block 50 is provided with an escape groove to prevent contact with the flux applied to the lower surface (bump-formed surface) of the semiconductor chip 1001.

The bonding head 60 suctions the semiconductor chip 1001 on the die block 50 and moves it above the substrate on the bonding table 80. The bonding head 60 comprises a heating member 63 to heat and press the semiconductor chip 1001 on the substrate for thermocompression bonding.

FIG. 3 is a configuration diagram showing the flow of the thermocompression bonding process using the bonding head 60 in the semiconductor chip bonding apparatus 1000.

Referring to FIG. 3, the bonding head 60 includes: a bonding tool 62 having a suction hole is formed therein for suctioning the semiconductor chip 1001; a heating block 61 provided on the upper portion of the bonding tool 62, having s a tool passage 201 formed therein for attaching and detaching the bonding tool 62 and a chip passage 204 communicating with the suction hole, and including a heating member 63; a tool flow path 202 communicating with the tool passage 201; a tool ejector 210 for supplying negative pressure or positive pressure to suction or detach the bonding tool 62 through the tool flow path 202; a chip flow path 205 communicating with the chip passage 204; a chip ejector 220 for supplying negative pressure or positive pressure to suction or detach the semiconductor chip 1001 through the chip flow path 205; a cleaning flow path 260 communicating with the tool flow path 202 and the chip flow path 205; and a cleaning air supply unit (not shown) for supplying air to remove solidified fume inside the tool passage 201 and the chip passage 204 through the cleaning flow path 260.

First, the bonding tool 62 is formed with a suction hole for suctioning the semiconductor chip and is detachably mounted on the lower portion of the heating block 61 to be replaceable according to the type and size of the semiconductor chip to be handled.

The heating block 61 is provided on the upper portion of the bonding tool 62. Inside the heating block 61, preferably in the lower portion of the heating block 61, a heating member 63 is provided. The bonding head 60 suctions the bonding tool 62 to the lower portion of the heating member 63 and suctions the semiconductor chip 1001 to be thermocompression bonded to the substrate to the lower surface (suction surface) of the bonding tool 62.

The heating block 61 is formed with a tool passage 201 for attaching and detaching the bonding tool 62 and a chip passage 204 communicating with the suction hole of the bonding tool 62.

The bonding head 60 comprises a tool flow path 202 communicating with the tool passage 201 and a chip flow path 205 communicating with the chip passage 204. The tool ejector 210 can supply negative pressure or positive pressure through the tool flow path 202 to suction or detach the bonding tool 62, and the chip ejector 220 can supply negative pressure or positive pressure through the chip flow path 205 to suction or detach the semiconductor chip 1001.

In other words, the bonding head 60 of the present invention comprises a tool flow path 202 connected to the bonding tool 62 to supply negative pressure through the tool ejector 210 to suction the bonding tool 62 to the heating block 61 or to supply positive pressure to separate the bonding tool 62 from the heating block 61, and a chip flow path 205 connected to the semiconductor chip 1001 to supply negative pressure through the chip ejector 220 to suction the semiconductor chip 1001 to the bonding tool 62 or to supply positive pressure to separate the semiconductor chip 1001 from the bonding tool 62.

More specifically, the bonding head 60 of the present invention comprises a tool passage 201 provided inside the heating block 61 of the bonding head 60 for attaching and detaching the bonding tool 62 and a tool flow path 202 connected to the tool passage 201 from the outside of the bonding head 60. The bonding head 60 of the present invention comprises a chip passage 204 provided separately from the tool flow path 202 inside the heating block 61 of the bonding head 60 for suctioning or detaching the semiconductor chip 1001 and a chip flow path 205 connected to the chip passage 204 from the outside of the bonding head 60.

Here, the tool flow path 202 and the chip flow path 205 communicate with the cleaning flow path 260. The cleaning flow path 260 is connected to a cleaning air supply unit (not shown), and the cleaning air supply unit (not shown) supplies air through the cleaning flow path 260 to remove solidified fume inside the tool passage 201 and the chip passage 204.

Therefore, when air is supplied by the cleaning air supply unit (not shown), air is delivered to each of the tool flow path 202 and the chip flow path 205 through the cleaning flow path 260, enabling the tool passage 201 and the chip passage 204 of the heating block 61 to be cleaned with air.

At this time, the bonding head 60 of the present invention comprises a tool valve 270, which is provided between the tool ejector 210 and the tool flow path 202. The tool valve 270 switches the cleaning flow path 260 to communicate with the tool flow path 202 for delivering cleaning air to the tool passage 201 and the chip passage 204, or switches the tool ejector 210 to communicate with the tool flow path 202 for delivering negative or positive pressure to the tool passage 201 and the chip passage 204 during the thermocompression bonding operation.

Additionally, a chip valve 280 is provided between the chip ejector 220 and the chip flow path 205 to switch the cleaning flow path 260 to communicate with the chip flow path 205 or to switch the chip ejector 220 to communicate with the chip flow path 205. Furthermore, it is preferable to provide a cleaning valve 250 on one side of the cleaning air supply unit (not shown) to selectively supply air through the cleaning flow path 260.

The tool valve 270 can switch the direction to communicate the tool flow path 202 with either the tool ejector flow path 211 of the tool ejector 210 or the cleaning flow path 260, and the chip valve 280 can switch the direction to communicate the chip flow path 205 with either the chip ejector flow path 221 of the chip ejector 220 or the cleaning flow path 260. The cleaning valve 250 opens to supply air during the cleaning operation and closes to block the air supply when the cleaning operation is not performed.

Meanwhile, during the thermocompression bonding process of the bonding head 60, the direction of the tool valve 270 is switched to communicate the tool ejector flow path 211 with the tool flow path 202. In FIG. 3, the arrow shown on the tool valve 270 indicates the connection direction of the tool valve 270 switched to communicate the tool ejector flow path 211 with the tool flow path 202.

The tool ejector 210 can supply negative pressure to suction the bonding tool 62 to the tool flow path 202 through the tool ejector flow path 211 by the tool valve 270 switched to the direction communicating the tool ejector flow path 211 with the tool flow path 202. In FIG. 3, the arrows shown around the tool ejector flow path 211 and the tool flow path 202 indicate the direction of air flowing through the tool ejector flow path 211 and the tool flow path 202 by the tool ejector 210. The semiconductor chip bonding apparatus 1000 can supply negative or positive pressure to the bonding tool 62 through the tool ejector flow path 211, the tool flow path 202, and the tool passage 201 via the tool valve 270. Accordingly, the bonding tool 62 can be suctioned to the lower portion of the heating member 63 of the heating block 61 or separated as needed.

Additionally, during the thermocompression bonding process of the bonding head 60, the direction of the chip valve 280 is switched to communicate the chip ejector flow path 221 with the chip flow path 205. In FIG. 3, the arrow shown on the chip valve 280 indicates the connection direction of the chip valve 280 switched to communicate the chip ejector flow path 221 with the chip flow path 205.

The chip ejector 220 can supply negative pressure to suction the semiconductor chip 1001 to the chip flow path 205 through the chip ejector flow path 221 by the chip valve 280 switched to the direction communicating the chip ejector flow path 221 with the chip flow path 205. In FIG. 3, the arrows shown around the chip ejector flow path 221 and the chip flow path 205 indicate the direction of air flowing through the chip ejector flow path 221 and the chip flow path 205 by the chip ejector 220. The semiconductor chip bonding apparatus 1000 can supply negative or positive pressure to the semiconductor chip 1001 through the chip ejector flow path 221, the chip flow path 205, and the chip passage 204 via the chip valve 280. Accordingly, the semiconductor chip 1001 to be thermocompression bonded to the substrate on the bonding table 80 can be suctioned to the lower surface (suction surface) of the bonding tool 62 or separated from the lower surface (suction surface) of the bonding tool 62 and smoothly transferred and bonded to the substrate.

During the thermocompression bonding process, the bonding head 60 performs thermocompression bonding by heating and pressing the semiconductor chip 1001 on the substrate while suctioning the bonding tool 62 and the semiconductor chip 1001 through the negative pressure supplied to the tool flow path 202 and the chip flow path 205, respectively.

As the bonding head 60 is heated to a high temperature by the heating member 63 during the thermocompression bonding process, the bumps and flux applied to the lower surface of the semiconductor chip 1001 are heated, generating fume.

However, the fume 2000 may scatter and be suctioned into the tool flow path (specifically, the tool passage 201) and the chip flow path (specifically, the chip passage 204) inside the heating block 61 or may adhere to the semiconductor chip 1001 and the substrate. Particularly, the tool passage 201 and the chip passage 204 maintain low internal pressure to suction the bonding tool 62 and the semiconductor chip 1001, so even small gaps allow the fume 2000 generated externally to easily enter the passages.

The fume 2000 suctioned into the tool passage 201 and the chip passage 204 condenses or solidifies inside, adhering to the inner walls of the tool passage 201 and the chip passage 204 or the tool flow path 202 and the chip flow path 205, causing a problem of reducing vacuum suction efficiency. Therefore, it is required to minimize the amount of fume 2000 suctioned into the tool passage 201, the chip passage 204, the tool flow path 202, and the chip flow path 205 during bonding.

To address this, the semiconductor chip bonding apparatus 1000 comprises a fume collection member 120 surrounding the heating block 61 of the bonding head 60 from the lower outer side. Preferably, the fume collection member 120 is disposed on the outer circumference of the heating block 61 to collect and remove vaporized fume generated during the thermocompression bonding of the semiconductor chip 1001 to the substrate.

The fume collection member 120 may comprise a suction pipe having one or more suction holes formed therein for suctioning the fume generated when the semiconductor chip 1001 is thermocompression bonded to the substrate, and the fume generated during bonding can be suctioned and removed through the suction holes formed in the suction pipe.

At this time, the suction holes formed in the suction pipe may be provided in the form of vertical suction holes penetrating vertically in the up-and-down direction or in the form of inclined suction holes inclined toward the semiconductor chip 1001. Additionally, it is permissible to appropriately mix and arrange vertical suction holes and inclined suction holes.

The fume collection member 120 communicates with a dust collection pump 231 through a dust collection flow path 230, and the dust collection flow path 230 is connected to the suction pipe of the fume collection member 120. More specifically, the semiconductor chip bonding apparatus 1000 of the present invention may comprise a dust collection flow path 230 communicating with one end of the fume collection member 120, a dust collection pump 231 communicating with the other end of the dust collection flow path 230 to collect the fume 2000 suctioned through the dust collection flow path 230, and a dust collection filter 232 provided on the dust collection flow path 230 to filter the suctioned fume.

The dust collection pump 231 of the present invention further comprises a recovery switching valve 233 capable of switching the suction direction between the dust collection pump 231 and the dust collection flow path 230 to suction vaporized fume from the fume collection member 120 or the fume collection unit 100. The recovery switching valve 233 of the present invention can communicate the dust collection pump 231 with the dust collection flow path 230 to suction vaporized fume through the fume collection member 120 or communicate the dust collection pump 231 with the fume collection unit flow path 240 to suction fume through the fume collection unit 100, which will be described later.

Referring to FIG. 3, during the thermocompression bonding process, the semiconductor chip bonding apparatus 1000 switches the direction of the recovery switching valve 233 to communicate the dust collection pump 231 with the dust collection flow path 230. The arrow shown on the recovery switching valve 233 in FIG. 3 indicates the connection direction of the recovery switching valve 233 switched to communicate the dust collection pump 231 with the dust collection flow path 230.

Through this, the semiconductor chip bonding apparatus 1000 can suction the fume 2000 scattered around the semiconductor chip 1001 into the fume collection member 120 and the dust collection flow path 230 and discharge it externally through the dust collection pump 231. In FIG. 3, the arrows shown around the dust collection flow path 230 and the dust collection pump 231 indicate the direction of air suctioned to collect the fume 2000 suctioned into the fume collection member 120.

The semiconductor chip bonding apparatus 1000 can filter and remove the fume 2000 suctioned into the fume collection member 120 through the dust collection filter 232 on the dust collection flow path 230 and discharge the filtered air through the dust collection pump 231. The dust collection filter 232 is a filter for filtering impurities such as fume in the air flowing through the dust collection flow path, and an air filter can be used as an example.

That is, compressed air (air) and vaporized fume created inside the dust collection flow path 230 can be filtered by being introduced into the dust collection filter 232, where the compressed air rotates through a deflector, causing the fume to adhere to the wall and fall downward. To this end, the dust collection filter 232 may be provided with a recovery container (not shown) below the dust collection filter 232 to collect the filtered fume. Therefore, the fume suctioned through the dust collection flow path 230 does not flow into the dust collection pump 231 due to the dust collection filter 232.

If the fume 2000 flows into the dust collection pump 231 without being filtered, it may contaminate and degrade the performance of the dust collection pump 231, and if discharged externally, it may cause contamination of the external device and air pollution problems. The semiconductor chip bonding apparatus 1000 of the present invention can prevent contamination problems by filtering the fume 2000 suctioned into the fume collection member 120 through the dust collection filter 232 and then discharging it through the dust collection pump 231.

As described above, the semiconductor chip bonding apparatus 1000 removes the fume 2000 scattered around the semiconductor chip 1001 during the thermocompression bonding process through the fume collection member 120.

Meanwhile, after completing the thermocompression bonding process, the semiconductor chip bonding apparatus 1000 performs a cleaning process (fume collection process) to remove the fume 2000 that was not suctioned into the fume collection member 120 and was suctioned into the tool passage 201 and the chip passage 204, contaminating the inside of the passages.

That is, during thermocompression bonding, vaporized fume generated during bonding can be suctioned and removed through the fume collection member 120, and in cases where the fume is not removed through the fume collection member 120 and enters the tool passage 201 and the chip passage 204 through fine gaps in the bonding tool 62 or between the bonding tool 62 and the semiconductor chip 1001, and solidifies or condenses, the solidified and condensed fume can be removed by supplying air through a cleaning air supply unit (not shown) to clean the tool passage 201 and the chip passage 204 of the bonding head 60.

At this time, the fume solidified by cleaning the tool passage 202 and the chip passage 204 can be collected and removed through the fume collection unit 100. Specifically, the fume collection unit 100 is provided below the movement path of the bonding head 60 and can collect the fume discharged to the lower part of the bonding head 60 during the cleaning process of the tool passage 201 and the chip passage 204 using air supplied by the cleaning air supply unit (not shown) in a state where the bonding tool 62 is separated from the bonding head 60.

Referring to FIG. 2, the semiconductor chip bonding apparatus 1000 may further comprise a cleaning flow path 260, one end of which is connected to the tool flow path 202 and the other end of which is connected to the chip flow path 205, and a cleaning air supply unit (not shown) for supplying air to the cleaning flow path 260.

The cleaning air supply unit (not shown) can supply air to the tool passage 201 through the tool flow path 202 via the cleaning flow path 260 and supply high-pressure air to the chip passage 204 through the chip flow path 205 via the cleaning flow path 260 to remove the solidified fume inside the tool passage 201 and the chip passage 204 through the cleaning flow path 260.

In the case of the semiconductor chip bonding apparatus 1000 of the present invention, to remove contaminants or oxides on the metal that interfere with soldering during bonding of the semiconductor chip 1001, improve the surface tension of the bumps (solder), and enhance the wetting effect so that the solder can diffuse well into the metal to be soldered, flux is applied to the bumps of the semiconductor chip 1001, and then bonding is performed.

During the process in which the bonding head 60 thermocompression bonds the semiconductor chip 1001, to which flux has been applied, to the substrate, the flux is heated, and gasified fume is generated. Fume has a property of changing its state depending on the temperature, maintaining a liquid state at room temperature, and when heated, the volatile components volatilize into a gaseous state and are gasified. When the gasified volatile components are cooled to room temperature, they condense and then either liquefy or solidify into a liquid or solid state.

Therefore, in the present invention, although referred to as fume, this fume is not limited to the gaseous state of gasified flux but includes solidified fume, liquefied fume, and gasified fume depending on the state.

In the present invention, during bonding, the flux and bumps are heated to high temperatures, and the fume generated by the heating of the flux can enter the tool passage 201 and the chip passage 204, where it may condense or solidify inside the passages. At this time, the tool passage 201 and the chip passage 204, contaminated by the condensed or solidified fume, can be cleaned with air to remove the fume.

The bonding head 60 of the present invention may further comprise a tool valve 270 and a chip valve 280 for switching the connection state of the tool passage 201 and the chip passage 204 with the cleaning flow path 260 so that air for cleaning can be delivered to the tool passage 201 and the chip passage 204 only when cleaning of the tool passage 201 and the chip passage 204 is necessary, and a cleaning valve 250 provided on one side of the cleaning air supply unit (not shown) to selectively supply air.

Additionally, the semiconductor chip bonding apparatus 1000 of the present invention comprises a fume collection unit 100 below the cleaning valve 250 and the bonding head 60, where the fume 2000 discharged from the tool passage 201 and the chip passage 204 by the cleaning air is dropped.

The fume collection unit 100 of the present invention can collect the fume dropped from the tool passage 201 and the chip passage 204 below the movement path of the bonding head 60. Here, the fume dropped to the fume collection unit 100 may be liquefied fume or vaporized fume. At this time, one side of the fume collection unit 100 may be connected to a fume collection unit flow path 240 connected to the aforementioned dust collection pump 231 to suction the vaporized fume. The dust collection pump 231 can suction air, thereby enabling it to suction the vaporized fume, scattered fume, and surrounding air together while guiding the liquefied and vaporized fume dropped to the fume collection unit 100 to the fume collection unit 100.

That is, the liquefied fume is dropped and retained at the lower part of the fume collection unit 100, and the vaporized fume can be suctioned and removed through the fume collection unit flow path 240, and by collecting the surrounding air, a suction airflow toward the fume collection unit 100 can be formed, so that the fume discharged at high pressure and dropped to the fume collection unit 100 can be guided back to the fume collection unit 100 along with the surrounding air, even if it is scattered outside the fume collection unit 100. Additionally, a dust collection filter 232 for filtering the suctioned fume may be provided in the fume collection unit flow path 240, and by filtering impurities in the vaporized fume and air flowing through the fume collection unit flow path 240 via the dust collection filter 232, the liquid-state fume suctioned through the fume collection unit flow path 240 is prevented from entering the dust collection pump 231.

At this time, when the liquefied and vaporized fume drops to the fume collection unit 100, the liquefied fume is guided to the bottom surface of the fume collection unit 100 and does not adhere to the inner wall where the fume collection unit flow path 240 communicates. A scattering prevention plate 101, which is formed to protrude in a downwardly inclined form toward the bottom surface of the fume collection unit 100 on the upper portion of the inner wall of the fume collection unit 100, may be provided.

The scattering prevention plate 101 is formed in a shape having an inclined portion on the upper side and a straight portion on the lower side, and is installed on the inner wall of the fume collection unit 100. It is preferably provided on the upper portion of the area where the fume collection unit 100 communicates with the fume collection unit flow path 240 to prevent the liquefied fume from adhering to the fume collection unit flow path 240 when the liquefied fume is introduced into the fume collection unit flow path 240 by the pneumatic pressure of the dust collection pump 231. The scattering prevention plate 101 may also perform the function of guiding the fume dropped to the fume collection unit 100 toward the bottom surface of the fume collection unit 100 or the fume collection unit flow path 240 side, without scattering outside the fume collection unit 100.

Hereinafter, the cleaning process of the present invention will be described in more detail with reference to the drawings.

Referring to FIG. 3, in the semiconductor chip bonding apparatus 1000, during the thermocompression bonding process, the cleaning valve 250 is closed so that air is not supplied to the cleaning flow path 260, and the tool flow path 202 and the chip flow path 205 are respectively connected to the tool ejector flow path 211 and the chip ejector flow path 221, allowing the bonding operation to be performed with the connection directions of the tool valve 270 and the chip valve 280 switched.

Referring to FIG. 4, after performing the thermocompression bonding process, the bonding head 60 moves to the upper portion of the tool changer 90 when it is determined that cleaning of the passages of the bonding head 60 is necessary. Such passage cleaning may be performed under various working conditions, such as when a predetermined number of bonding operations have elapsed, a predetermined bonding time has elapsed, or the type of semiconductor chip 1001 to be bonded is changed.

The tool changer 90 is provided below the movement path of the bonding head 60 and may have a plurality of seating grooves formed so that tools of the same or different types can be seated according to the type of semiconductor chip 1001. At this time, each seating groove may be provided with a suction hole so that the tool can be suctioned.

First, before performing passage cleaning, the bonding head 60 of the present invention can move to the upper portion of the tool changer 90 to separate the bonding tool 62 from the heating block 61 of the bonding head 60.

Here, the bonding tool 62 is separated from the heating block 61 by supplying positive pressure to the tool flow path 202 and the tool passage 201 through the tool ejector 210. As a result, the bonding tool 62, which is suctioned to the lower portion of the heating block 61, is transferred to the seating groove of the tool changer 90, and during the process of transferring the bonding tool 62 to the seating groove, the seating groove suctions the bonding tool 62, making it easier to separate the bonding tool 62 from the heating block 61.

For reference, when performing the bonding process using the semiconductor chip bonding apparatus 1000, the tool flow path 202 and the chip flow path 205 are connected to the tool ejector 210 and the chip ejector 220, respectively. In this state, negative pressure is delivered to the tool flow path 202 by the tool ejector 210, so that the bonding tool 62 is suctioned. When the semiconductor chip 1001 is suctioned to the bonding tool 62 by the chip ejector 220, negative pressure is delivered to the semiconductor chip 1001. After the semiconductor chip 1001 is bonded to the substrate, positive pressure is delivered so that the semiconductor chip 1001 is separated from the bonding tool 62.

Then, the bonding head 60 moves to the upper portion of the fume collection unit 100 to perform a cleaning process to remove the solidified fume 2000 inside the tool flow path 202, tool passage 201, chip flow path 205, and chip passage 204.

Referring to FIG. 2, the semiconductor chip bonding apparatus 1000 performs a cleaning process to remove fume 2000 present in each of the tool flow path 202 and the chip flow path 205 while the bonding head 60 is positioned above the fume collection unit 100.

First, the semiconductor chip bonding apparatus 1000 moves the bonding head 60 to the upper portion of the fume collection unit 100. Then, the heating member 63 is heated to liquefy the solidified fume present in each of the tool passage 201 and the chip passage 204 by heating them.

Before the heating member 63 heats the heating block 61, the fume remaining inside the tool passage 201 and the chip passage 204 is condensed and solidified, adhering to and remaining in each passage. In this state, when air is sprayed by the cleaning air supply unit (not shown), some of the condensed liquid-state fume may drop to the fume collection unit 100, but the solidified fume cannot be removed.

Therefore, to easily remove the solidified fume remaining inside the tool passage 201 and the chip passage 204, the heating member 63, which heats the semiconductor chip 1001 during bonding, is used to first heat the surroundings of the heating block 61, thereby liquefying and vaporizing the solidified fume inside the tool passage 201 and the chip passage 204. At this time, when the surroundings of the heating block 61 are heated, not only the tool passage 201 and the chip passage 204 but also the tool flow path 202 and the chip flow path 205, which communicate with the tool passage 201 and the chip passage 204, respectively, can be heated, and the solidified fume inside the tool flow path 202 and the chip flow path 205 can also be liquefied and vaporized together.

During the cleaning process, the tool valve 270 is switched to connect the cleaning flow path 260 with the tool flow path 202. More specifically, the tool valve 270 is configured to be switchable to connect the tool ejector flow path 211 with the tool flow path 202 or to connect the cleaning flow path 260 with the tool flow path 202. Accordingly, the tool valve 270 is switched to a direction connecting the tool ejector flow path 211 with the tool flow path (specifically, the tool flow path 202) during the thermocompression bonding process, and to a direction connecting the cleaning flow path 260 with the tool flow path (specifically, the tool flow path 202) during the cleaning process.

The chip valve 280 is switched to connect the cleaning flow path 260 with the chip flow path 205. More specifically, the chip valve 280 is configured to be switchable to connect the chip ejector flow path 221 with the chip flow path 205 or to connect the cleaning flow path 260 with the chip flow path 205. Accordingly, the chip valve 280 is switched to a direction connecting the chip ejector flow path 221 with the chip flow path (specifically, the chip flow path 205) during the thermocompression bonding process, and to a direction connecting the cleaning flow path 260 with the chip flow path (specifically, the chip flow path 205) during the cleaning process.

Here, the switching of the tool valve 270 and the chip valve 280 may be performed simultaneously with heating the heating block 61 by the heating member 63, or after heating the heating block 61 by the heating member 63 to liquefy and vaporize the fume inside the tool passage 201 and the chip passage 204, the switching of the tool valve 270 and the chip valve 280 may also be performed. Alternatively, the switching of the tool valve 270 and the chip valve 280 may be performed in advance before liquefying and vaporizing the fume inside the tool passage 201 and the chip passage 204.

When the direction of the tool valve 270 and the chip valve 280 is switched, and the tool flow path 202 and the cleaning flow path 260 are connected, and the chip flow path 205 and the cleaning flow path 260 are connected, if air supply by the cleaning air supply unit (not shown) is performed, the air can be delivered to the tool passage 201 and the chip passage 204 through the tool flow path 202 and the chip flow path 205. At this time, the air supply by the cleaning air supply unit (not shown) may be performed simultaneously with heating the heating block 61 by the heating member 63, or it may be performed after heating the heating block 61 to liquefy and vaporize the fume inside the tool passage 201 and the chip passage 204. However, it is preferable that the heating by the heating member 63 continues during the air supply.

To ensure that this air supply is performed at an appropriate timing, the cleaning air supply unit (not shown) is provided with a cleaning valve 250 for selectively supplying air. Preferably, the cleaning valve 250 is opened later than the heating timing of the heating member 63 to allow the heating block 61 and its surroundings to be quickly heated by the heating member 63, thereby supplying air.

At this time, instead of cleaning the tool passage 201 and the chip passage 204 with the positive pressure of the tool ejector 210 and the chip ejector 220, the tool passage 201 and the chip passage 204 are cleaned with air supplied by a separate cleaning air supply unit (not shown), enabling effective cleaning of the passages with strong air pressure. The negative and positive pressures of the chip ejector 220 applied when picking up or releasing the semiconductor chip 1001 in the semiconductor chip bonding apparatus 1000 are formed at low pressure to avoid impacting the thin semiconductor chip 1001. Therefore, since the positive pressure of the chip ejector 220 is low, it is difficult to easily remove the fume remaining inside the chip passage 204 when cleaning the chip passage 204 with low positive pressure.

Accordingly, in the present invention, to effectively remove the fume inside the tool passage 201 and the chip passage 204, it is preferable that the pressure of the air supplied by the cleaning air supply unit (not shown) is greater than the positive pressure of the chip ejector 220 for detaching the semiconductor chip 1001 from the bonding tool 62.

During the cleaning process of the present invention, the semiconductor chip bonding apparatus 1000 does not perform the process of removing fume 2000 through the fume collection member 120 provided in the bonding head 60. Therefore, the recovery switching valve 233 is switched to connect the fume collection unit flow path 240, one end of which is connected to the fume collection unit 100 and the other end of which is connected to the recovery switching valve 233, with the dust collection pump 231.

That is, in the present invention, the recovery switching valve 233 is provided at a position where the fume collection unit flow path 240 of the fume collection unit 100 and the dust collection flow path 230 on the bonding head 60 side communicate, and the recovery switching valve 233 switches the suction direction of the dust collection pump 231 from the dust collection flow path 230 side to the fume collection unit flow path 240 side.

In the present invention, to clean the tool passage 201 and the chip passage 204 of the heating block 61 constituting the bonding head 60, the heating block 61 is heated by the heating member 63 to liquefy and vaporize the solidified fume remaining inside the tool passage 201 and the chip passage 204. Then, the cleaning valve 250 is opened to supply air from the cleaning air supply unit (not shown) to the cleaning flow path 260. At this time, not only the tool passage 201 and the chip passage 204 but also the tool flow path 202 communicating with the tool passage 201 and the chip flow path 205 communicating with the chip passage 204 can be heated together, and the liquefied and vaporized fume inside the tool flow path 202 and the tool passage 201 can be dropped to the fume collection unit 100 side by passing through the tool flow path 202 and the tool passage 201 by the air supplied from the cleaning air supply unit (not shown). Similarly, the liquefied and vaporized fume inside the chip flow path 205 and the chip passage 204 can be dropped to the fume collection unit 100 side by passing through the chip flow path 205 and the chip passage 204 by the air supplied from the cleaning air supply unit (not shown).

Referring to FIG. 2 for a more detailed explanation, the arrows shown around one side of the cleaning flow path 260 connected to the tool flow path 202 indicate the flow direction of the air supplied to the tool flow path 202 through the cleaning flow path 260. Also, the arrows shown around the other side of the cleaning flow path 260 connected to the chip flow path 205 in FIG. 2 indicate the flow direction of the air supplied to the chip flow path 205 through the cleaning flow path 260.

The semiconductor chip bonding apparatus 1000 comprises a cleaning valve 250 that can be selectively opened and closed.

The semiconductor chip bonding apparatus 1000 opens the cleaning valve 250 during the cleaning process to introduce air into the cleaning flow path 260. The cleaning flow path 260 branches in both directions, one direction having the tool flow path 202 and the other direction having the chip flow path 205, to deliver air to each of the tool flow path 202 and the chip flow path 205.

The air supplied from the cleaning air supply unit (not shown) flows into the tool flow path 202 through one side of the cleaning flow path 260 and is delivered to the tool passage 201. The supplied air is discharged through the opening of the tool passage 201, removing the liquefied and vaporized fume 2000 present inside the tool passage 201, and is discharged along with the fume 2000 to the fume collection unit 100 side. The fume 2000 is discharged outside the tool passage 201 by the air and drops to the fume collection unit 100 separately provided below the bonding head 60.

Additionally, the air flows into the chip flow path 205 through the other side of the cleaning flow path 260 and is delivered to the chip passage 204. The air is discharged through the opening of the chip passage 204, removing the liquefied and vaporized fume 2000 present in the chip passage 204, and is discharged along with the fume to the fume collection unit 100 side. The fume 2000 is discharged outside the chip passage 204 by the cleaning air and drops to the fume collection unit 100 separately provided below the bonding head 60.

When the semiconductor chip bonding apparatus 1000 performs the process of removing the fume 2000 from the tool passage 201 and the chip passage 204 through air, the dust collection pump 231 suctions the air inside and outside the fume collection unit 100 through the fume collection unit flow path 240 and discharges it outside along the fume collection unit flow path 240. A dust collection filter 232 is provided on the fume collection unit flow path 240. The air suctioned into the fume collection unit flow path 240 is filtered once through the dust collection filter 232 and moves toward the dust collection pump 231.

During the cleaning process, the liquefied and vaporized fume 2000 and air are discharged to the fume collection unit 100. At this time, most of the liquefied and vaporized fume 2000 and air are collected inside the fume collection unit 100. However, during the process of discharging the liquefied and vaporized fume 2000 and air, some of the fume may scatter to the surrounding outside without dropping to the fume collection unit 100, causing secondary contamination. Even if collected inside the fume collection unit 100, the fume may be discharged along with the high-pressure air, collide with the inner wall of the fume collection unit 100, and scatter outside again.

To prevent this, the air inside and outside the fume collection unit 100 is suctioned through the fume collection unit flow path 240 of the fume collection unit 100, making it easier to guide the liquefied and vaporized fume into the fume collection unit 100.

In addition, the fume collection unit 100 suctions vaporized fume among the liquefied and vaporized fume dropped into the fume collection unit 100 by discharging the air inside the fume collection unit 100 to the outside through the dust collection pump 231. By filtering through the dust collection filter 232, the vaporized fume is removed from the fume collection unit 100, thereby minimizing the problem of the vaporized fume scattering back to the outside of the fume collection unit 100.

To this end, inside the fume collection unit 100, a scattering prevention plate 101 is provided on the upper portion of the inner wall of the fume collection unit 100, protruding in a downwardly inclined form toward the bottom surface of the fume collection unit 100, so that when the liquefied and vaporized fume dropping into the fume collection unit 100 is guided to the bottom surface of the fume collection unit 100, it does not adhere to the inner wall where the fume collection unit flow path 240 communicates. Through the scattering prevention plate 101, the liquefied fume flows down to the bottom surface for collection, and the vaporized fume is covered by the scattering prevention plate 101, preventing it from scattering through the opening of the fume collection unit 100.

Additionally, the scattering prevention plate 101 may be formed to extend below the inlet of the fume collection unit flow path 240, allowing the relatively heavier liquefied fume among the liquefied and vaporized fume introduced into the fume collection unit 100 to drop to the bottom surface of the fume collection unit 100, while only the lighter vaporized fume is allowed to flow into the fume collection unit flow path 240.

The semiconductor chip bonding apparatus 1000 of the present invention comprises a cleaning flow path 260, which communicates with each of the tool flow path 202 and the chip flow path 205 through directional switching of a tool valve 270, and a cleaning valve 250 for supplying air to the cleaning flow path 260. Even if vaporized fume generated during thermocompression bonding flows into the tool passage 201 and the chip passage 204 of the bonding tool 62 and solidifies inside the tool passage 201 and the chip passage 204, the cleaning process of the present invention liquefies and vaporizes the solidified fume 2000 inside the tool passage 201 and the chip passage 204 of the bonding head 60, dropping it into the fume collection unit 100. This allows the tool passage 201 and the chip passage 204 contaminated by the fume to be automatically removed and then cleaned.

Conventionally, to remove the fume 2000 present in the tool flow path 202 and the chip flow path 205 of the bonding head 60, an operator manually separated the bonding tool 62 and the heating block 61 from the bonding head 60 to perform the cleaning process. This made the cleaning process cumbersome, as the operator had to directly separate the heating block 61 from the bonding head 60 and perform the cleaning process using separate cleaning equipment, thereby reducing the efficiency of the cleaning process.

However, the semiconductor chip bonding apparatus 1000 of the present invention has a structure in which the tool flow path 202 and the chip flow path 205 are each connected to the cleaning flow path 260 through the respective tool valve 270 and chip valve 280, which are capable of directional switching. Specifically, the tool valve 270 is provided between the tool ejector 210 and the tool flow path 202, allowing the cleaning flow path 260 to communicate with the tool flow path 202 or the tool ejector 210 to communicate with the tool flow path 202. The chip valve 280 is provided between the chip ejector 220 and the chip flow path 205, allowing the cleaning flow path 260 to communicate with the chip flow path 205 or the chip ejector 220 to communicate with the chip flow path 205.

Therefore, during the thermocompression bonding process, the semiconductor chip bonding apparatus 1000 blocks the flow of cleaning air to the cleaning flow path 260 by keeping the cleaning valve 250 closed. During the thermocompression bonding process, the semiconductor chip bonding apparatus 1000 suctions the bonding tool 62 by connecting the tool ejector flow path 211 and the tool flow path 202 through the directional switching of the tool valve 270. It also suctions or releases the semiconductor chip 1001 by connecting the chip ejector flow path 221 and the chip flow path 205 through the directional switching of the chip valve 280.

On the other hand, during the cleaning process, the semiconductor chip bonding apparatus 1000 opens the cleaning valve 250 and switches the directions of the tool valve 270 and the chip valve 280 to directions different from those during thermocompression bonding, thereby connecting the tool flow path 202 and the chip flow path 205 to the cleaning flow path 260. This allows cleaning air to flow into the tool flow path 202 and the chip flow path 205, and, following the switching of the cleaning valve 250, removes the fume 2000 present inside the tool flow path 202 and the chip flow path 205, discharging it outside the bonding head 60 to clean the tool passage 201 and the chip passage 204.

In this way, the fume solidified in the tool passage 201 and the chip passage 204 is liquefied and vaporized by the heating of the heating member 63. The liquefied and vaporized fume is discharged outside the bonding head 60 by the air supplied from the cleaning air supply unit (not shown) and dropped into the fume collection unit 100.

The semiconductor chip bonding apparatus 1000 of the present invention switches the directions of the tool valve 270 and the chip valve 280 in response to the thermocompression bonding process and the cleaning process, respectively. As a result, the cleaning flow path 260 can be connected to or blocked from the tool flow path 202 and the chip flow path 205. Accordingly, the semiconductor chip bonding apparatus 1000 can automatically perform the cleaning process without requiring the operator to manually separate the heating block 61 of the bonding head 60. Thus, the semiconductor chip bonding apparatus 1000 improves the convenience and efficiency of the cleaning process.

Hereinafter, the fume collection method (cleaning process operation) of the bonding apparatus of the present invention will be briefly described.

The fume collection method of a semiconductor chip bonding apparatus 1000 for applying flux to a lower surface of a semiconductor chip 1001 on which bumps are formed and bonding the semiconductor chip 1001 to a substrate by heating and pressing the semiconductor chip 1001 to which the flux is applied, the method comprising: separating the bonding tool 62 from the heating block 61 by supplying positive pressure to the tool passage 291 in the bonding head 60 including the heating block 61 having the tool passage 201 and the chip passage 204 formed therein and including the heating member 63; liquefying and vaporizing solidified fume inside the tool passage 201 and the chip passage 204 by heating the heating member 63 in a state where the bonding tool 62 is separated; and a fume recovery step of, in a state where the tool valve 270 and the chip valve 280 are switched so that the cleaning flow path 260 is connected to the tool passage 201 and the chip passage 204, opening the cleaning valve 250 to supply air through the tool passage 201 and the chip passage 204 to drop the liquefied and vaporized fume, and recovering the dropped fume to the fume collection unit 100.

First, positive pressure is supplied to the tool flow path 202 from the tool ejector 210 of the bonding head 60. The positive pressure supplied to the tool flow path 202 is transmitted to the tool passage 201 of the heating block 61, and the bonding tool 62 adsorbed to the lower portion of the heating block 61 is separated from the heating block 61 by the positive pressure transmitted to the tool passage 201.

When the bonding tool 62 is separated from the heating block 61, the bonding head 60 moves to the upper portion of the fume collection unit 100. During the movement to the upper portion of the fume collection unit 100, the directions of the tool valve 270 and the chip valve 280 are switched to communicate with the cleaning flow path 260, and the direction of the recovery switching valve 233 is switched to allow the dust collection pump 231 to communicate with the fume collection unit 100. Subsequently, in the state where the bonding head 60 has moved to the upper portion of the fume collection unit 100, the heating member 63 heats the heating block 61. The heating of the heating member 63 also heats the tool passage 201 and the chip passage 204 formed in the heating block 61, liquefying and vaporizing the solidified fume inside the tool passage 201 and the chip passage 204. That is, most of the solidified fume is liquefied, but during the liquefaction process, some of the fume may vaporize due to heating. To remove the liquefied and vaporized fume, the cleaning valve 250 of the cleaning air supply unit (not shown) is opened.

It should be noted that the directional switching of the tool valve 270, the chip valve 280, and the recovery switching valve 233 may be performed before or after the bonding head 60 reaches the upper portion of the fume collection unit 100, or simultaneously with the heating of the heating member 63. Additionally, the opening of the cleaning valve 250 may also be performed simultaneously with the heating of the heating block 61 by the heating member 63 or during the heating process by the heating member 63. Furthermore, the heating of the heating member 63 may be terminated during the air supply, but it is preferable to terminate it after the cleaning is completed for smooth removal of the fume.

To enable the cleaning flow path 260 to communicate with the tool passage 201 and the chip passage 204, the tool valve 270 and the chip valve 280 are switched, and in the state where the cleaning flow path 260 is connected to the tool flow path 202 and the chip flow path 205 respectively, the cleaning valve 250 is opened to supply air through the tool flow path 202 and the chip flow path 205, discharging the liquefied and vaporized fume and allowing the fume dropped outside the bonding head 60 to be recovered to the fume collection unit 100.

At this time, since the recovery switching valve 233 is in an open state when recovering the dropped fume from the fume collection unit 100, the fume collection unit flow path 240 is connected to the dust collection pump 231, allowing the vaporized fume and even the air around the fume collection unit 100 to be collected.

As described above, the semiconductor chip bonding apparatus 1000 of the present invention uses low-pressure negative and positive pressure during the thermocompression bonding process to prevent damage to the semiconductor chip 1001, and uses high-pressure air pressure (positive pressure) during the cleaning process to improve the efficiency of fume 2000 removal.

Therefore, when the chip passage 204 is cleaned using the positive pressure of the chip ejector 220, the magnitude of the negative and positive pressure supplied to the chip passage 204 must also be increased. However, increasing this magnitude may cause greater impact on the semiconductor chip 1001 during picking up the semiconductor chip 1001 or releasing the semiconductor chip 1001, potentially damaging the semiconductor chip 1001.

Accordingly, the present invention can supply low-pressure negative or positive pressure through the chip ejector 220 when picking up or releasing the semiconductor chip 1001, and since a separate cleaning flow path 260 and cleaning valve 250 are provided for cleaning the tool passage 201 and the chip passage 204, it is possible to perform the automatic cleaning process using high-pressure air. Thus, high-pressure air can be used during the cleaning process, and low-pressure negative and positive pressure can be used during the thermocompression bonding process.

As a result, the semiconductor chip bonding apparatus 1000 of the present invention is equipped with a structure capable of using both high-pressure air and low-pressure air, thereby enhancing the efficiency of the processes performed by the semiconductor chip bonding apparatus 1000 itself.

Additionally, the semiconductor chip bonding apparatus 1000 of the present invention can perform the cleaning process of the tool passage 201 and the chip passage 204 by sequentially moving to the tool changer 90 and the fume collection unit 100 after performing the thermocompression bonding process of at least some of the semiconductor chips 1001.

Then, it can move back to the tool changer 90, adsorb a new bonding tool 62 seated in the receiving groove of the tool changer 90, and perform the thermocompression bonding process to bond the remaining semiconductor chips 1001 to the substrate.

At this time, the newly suctioned bonding tool 62 may be the same type of bonding tool 62 previously used if the size and type of the semiconductor chip 1001 to be handled have not changed. If the size and type have changed, a new bonding tool 62 suitable for the semiconductor chip 1001 may be suctioned. Since fume residues may remain on the upper and lower portions of the bonding tool 62 used for bonding, it would be preferable to use a new bonding tool 62.

After the tool passage 201 and the chip passage 204 of the heating block 61 of the bonding head 60 are cleaned, the heating of the heating member 63 is stopped, and the bonding head 60 moves to the upper portion of the tool changer 90 to perform the bonding operation. Before re-suctioning the bonding tool 62 on the tool changer 90, the cleaning valve 250 is closed. At the same time, the tool valve 270 is switched to a direction that connects the tool ejector flow path 211 and the tool flow path 202, and the chip valve 280 is switched to a direction that connects the chip ejector flow path 221 and the chip flow path 205. Additionally, the recovery switching valve 233 is switched to a direction that connects the dust collection flow path 230 and the dust collection pump 231.

The bonding head 60, after re-suctioning the bonding tool 62 from the tool changer 90, can suction the semiconductor chip 1001 onto the suction surface of the bonding tool 62 and perform the thermocompression bonding process on the substrate.

The semiconductor chip bonding apparatus 1000 of the present invention has a structure that, by comprising the cleaning flow path 260 and the cleaning valve 250, allows the tool flow path 202 and the chip flow path 205, as well as the tool passage 202 and the chip passage 204, to be automatically cleaned by connecting each of the tool flow path 202 and the chip flow path 205 with the cleaning flow path 260 through the direction-switchable tool valve 270 and chip valve 280, respectively, after performing the thermocompression bonding process.

As a result, the semiconductor chip bonding apparatus 1000, after performing the thermocompression bonding process, can improve the efficiency of the cleaning process by automatically performing the cleaning process to remove the fume 2000 suctioned into the tool flow path 202 and the chip flow path 205 of the bonding head 60, without the operator having to separately detach the bonding tool and the heating block 61 from the bonding head 60 and perform the cleaning process manually.

More specifically, in the thermocompression bonding process, the tool valve 270 is switched to connect the tool ejector flow path 211 and the tool flow path 202, and the chip valve 280 is switched to connect the chip ejector flow path 221 and the chip flow path 205. After performing the thermocompression bonding process, the tool valve 270 is switched to connect one side of the cleaning flow path 260 with the tool flow path 202, and the other side of the cleaning flow path 260 with the chip flow path 205. At this time, the bonding head 60 is preferably in a state where, after performing the thermocompression bonding process, the bonding tool 62 is seated on the tool changer 90 and moved to the upper portion of the fume collection unit 100. In this state, the semiconductor chip bonding apparatus 1000 automatically performs the cleaning process by opening the cleaning valve 250. During the cleaning process, the recovery switching valve 233 is switched to connect the fume collection unit flow path 240 and the dust collection pump 231.

In the cleaning process, unlike the thermocompression bonding process, high-pressure air (positive pressure) can be supplied through the cleaning flow path 260. As a result, the semiconductor chip bonding apparatus 1000 can more effectively discharge the fume 2000 suctioned into the tool flow path 202 and the chip flow path 205 during the thermocompression bonding process to the outside.

As described above, the semiconductor chip bonding apparatus 1000 can perform the cleaning process more quickly than a manual cleaning process by the operator by automatically performing the cleaning process through the cleaning valve 250 and the cleaning flow path 260 after the thermocompression bonding process. As a result, the semiconductor chip bonding apparatus 1000 can easily remove and collect fume.

Additionally, the semiconductor chip bonding apparatus 1000 of the present invention can quickly collect and remove the vaporized fume of flux generated during thermocompression bonding, thereby preventing contamination of the semiconductor chip 1001 and the bonding tool 62. Furthermore, it can prevent fume from entering the fine gaps of the bonding tool 62 or between the bonding tool 62 and the semiconductor chip 1001, thereby preventing malfunctions in the vacuum suction operation. Even if fume enters and solidifies in the tool passage 201 and the chip passage 204, the solidified fume in the tool passage 201 and the chip passage 204 of the heating block 61 can be liquefied and vaporized, discharged along with high-pressure air, and collected in the fume collection unit, where the liquefied fume is collected, and the vaporized fume is suctioned. This allows for quick and easy removal of fume, enabling the tool passage 201 and the chip passage 204 to be maintained in good condition.

As described above, although the preferred embodiments of the present invention have been described with reference to the above, those skilled in the art can make various modifications or changes to the present invention without departing from the spirit and scope of the invention as set forth in the following claims.

What is claimed is:

1. A semiconductor chip bonding apparatus for applying flux to a lower surface of a semiconductor chip on which bumps are formed, and bonding the semiconductor chip to a substrate by heating and pressing the semiconductor chip to which the flux is applied, the apparatus comprising:
a bonding head, wherein the bonding head comprises:
a bonding tool having a suction hole formed therein for suctioning the semiconductor chip;
a heating block provided on an upper portion of the bonding tool, having a tool passage formed therein for attaching and detaching the bonding tool and a chip passage communicating with the suction hole, and including a heating member;
a tool flow path communicating with the tool passage;
a tool ejector for supplying negative pressure or positive pressure to suction or detach the bonding tool through the tool flow path;
a chip flow path communicating with the chip passage; and
a chip ejector for supplying negative pressure or positive pressure to suction or detach the semiconductor chip through the chip flow path,
wherein the bonding head further comprises:
a cleaning flow path communicating with the tool flow path and the chip flow path; and
a cleaning air supply unit for supplying air to remove solidified fume inside the tool passage and the chip passage through the cleaning flow path.

2. The semiconductor chip bonding apparatus of claim 1, wherein:
the semiconductor chip bonding apparatus further comprises a fume collection unit for collecting fume discharged from the bonding head below a movement path of the bonding head,
the heating member heats the heating block in a state where the bonding tool is detached to liquefy and vaporize the solidified fume inside the tool passage and the chip passage, and
the cleaning air supply unit supplies air to the tool passage and the chip passage to drop the liquefied and vaporized fume to the fume collection unit.

3. The semiconductor chip bonding apparatus of claim 2, wherein the heating member heats the heating block before cleaning the tool flow path and the chip flow path with the air supplied from the cleaning air supply unit or simultaneously with the air supply from the cleaning air supply unit.

4. The semiconductor chip bonding apparatus of claim 2, further comprising:
a fume collection unit flow path communicating with the fume collection unit; and
a dust collection pump for guiding the liquefied and vaporized fume dropping to the fume collection unit to the fume collection unit, and suctioning the vaporized fume through the fume collection unit flow path when dropping to the fume collection unit.

5. The semiconductor chip bonding apparatus of claim 4, wherein:
the bonding head further comprises a fume collection member disposed on an outer circumference of the heating block and collecting vaporized fume generated when thermocompression bonding the semiconductor chip,
the semiconductor chip bonding apparatus further comprises:
a dust collection flow path having one end communicating with the fume collection member and the other end communicating with the fume collection unit flow path; and
a recovery switching valve provided at a position where the fume collection unit flow path and the dust collection flow path communicate, and switching a suction direction of fume toward the fume collection unit flow path or the dust collection flow path, and
the recovery switching valve is switched to:
suction the vaporized fume through the dust collection flow path when the bonding head thermocompression bonds the semiconductor chip, and
suction the vaporized fume through the fume collection unit flow path when the fume collection unit collects the liquefied and vaporized fume from the bonding head.

6. The semiconductor chip bonding apparatus of claim 5, wherein dust collection filters for filtering the suctioned fume are respectively provided on the fume collection unit flow path and the dust collection flow path.

7. The semiconductor chip bonding apparatus of claim 4, wherein the fume collection unit comprises a scattering prevention plate protruding in a downwardly inclined form toward a bottom surface of the fume collection unit on an upper portion of an inner wall of the fume collection unit so that when the liquefied and vaporized fume drops to the fume collection unit, the liquefied fume is guided to the bottom surface of the fume collection unit and does not adhere to the inner wall where the fume collection unit flow path communicates.

8. The semiconductor chip bonding apparatus of claim 1, wherein the bonding head further comprises:
a tool valve provided between the tool ejector and the tool flow path to switch the cleaning flow path to communicate with the tool flow path or to switch the tool ejector to communicate with the tool flow path;
a chip valve provided between the chip ejector and the chip flow path to switch the cleaning flow path to communicate with the chip flow path or to switch the chip ejector to communicate with the chip flow path; and
a cleaning valve provided on one side of the cleaning air supply unit to selectively supply air.

9. The semiconductor chip bonding apparatus of claim 1, wherein a pressure of the air supplied from the cleaning air supply unit is greater than a positive pressure of the chip ejector.

10. A fume collection method of a semiconductor chip bonding apparatus for applying flux to a lower surface of a semiconductor chip on which bumps are formed, and bonding the semiconductor chip to a substrate by heating and pressing the semiconductor chip to which the flux is applied, the method comprising:
separating a bonding tool from a heating block by supplying positive pressure to a tool passage in a bonding head including the heating block having the tool passage and a chip passage formed therein and including a heating member;
liquefying and vaporizing solidified fume inside the tool passage and the chip passage by heating the heating member in a state where the bonding tool is separated; and
a fume recovery step of, in a state where a tool valve and a chip valve are switched so that a cleaning flow path is connected to the tool passage and the chip passage, opening a cleaning valve to supply air through the tool passage and the chip passage to drop the liquefied and vaporized fume, and recovering the dropped fume to a fume collection unit.

11. The fume collection method of a semiconductor chip bonding apparatus of claim 10, wherein the fume recovery step suctions the vaporized fume through a fume collection unit flow path when the liquefied and vaporized fume drops to the fume collection unit by opening a recovery switching valve.
